(19) United States
(12) Patent Application Publication
(10) Pub. No.: US 2002/0196039 A1
(43) Pub. Date: Dec. 26, 2002

(54) Socket for testing a semiconductor package device

(76) Inventors: Jichen Wu, Hsinchu (TW); Burton Yang, Hsinchu (TW)

Correspondence Address: Keith Kline, PRO-TECHTOR INTERNATIONAL SERVICES, 20775 Norada Court, Saratoga, CA, 95070-3018, US

(21) Appl. No.: 10/147,137

(22) Filed: May 15, 2002

(30) Foreign Application Priority Data
Jun. 21, 2001 (TW) 090210464

(51) Int. Cl. G01R 31/02

(52) U.S. Cl. 324/755

(57) ABSTRACT

The invention provides a socket for testing a semiconductor package device having a plurality of to-be-tested points. The socket includes a pin board unit, a plurality of resilient members, a plurality of probe bodies, and a plurality of electroconductive elements. The pin board unit is formed with pin holes at positions corresponding to the to-be-tested points. The pin board unit is formed with a cavity for receiving the semiconductor package device. The resilient members are arranged within the pin holes, respectively. The probe bodies are inserted into the pin holes and in contact with the resilient members, respectively. Each electroconductive element has an upper section and a lower section. The upper sections are electrically connected to the resilient members, and the lower sections are exposed from the pin holes, respectively. Accordingly, when the semiconductor package device is received within the cavity, the to-be-tested points can be precisely aligned with the corresponding probe bodies, respectively.

### BACKGROUND OF THE INVENTION

1. Field of the invention

The invention relates to a socket for testing a semiconductor package device, and more specifically to a socket that is reusable and easy to be maintained so that the testing cost can be greatly lowered.

2. Description of the Related Art

In general, after having being packaged, the conductivities and functions of semiconductor devices have to be tested so as to screen out bad products generated by various factors during the packaging processes.

In a conventional testing method for a semiconductor package device, as shown in FIG. 1, a semiconductor package device 10 is placed within a test socket 12 for testing. The test socket 12 includes a base 14 and a plurality of probes 16. The base 14 is formed with a cavity 18 corresponding to the size of the semiconductor package device 10 so as to contain and position the semiconductor package device 10. The probes 16 are mounted, in the base 14, corresponding to the positions of the to-be-tested points 20 of the semiconductor package device 10. One end of each probe 16 penetrates through the base 14 and is located within the cavity 18 so as to contact the corresponding to-be-tested point 20 of the semiconductor package device 10. The other end of each probe 16 protrudes from the base 14 and is to be inserted into a predetermined through hole 24 formed in a printed circuit board 22. The printed circuit board 22 transmits the tested signals from the probes 16 to a test machine (not shown), so that the electroconductivity and function of the semiconductor package device 10 can be tested.

Because the semiconductor package device 10 directly contacts the probes 16, the probes 16 have to be configured to be resilient members so as to increase the buffer capability between the semiconductor package device 10 and the probes 16 and thus prevent the to-be-tested points 20 of the semiconductor package device 10 from being damaged. Referring to FIG. 2, which is an enlarged cross-sectional view of the probe 16, the probe 16 includes an outer sleeve 26, a resilient member 28 mounted within the outer sleeve 26, and a probe body 30 inserted into the outer sleeve 26 and pressing against the resilient member 28. Accordingly, the buffer effect can be created between the probe 16 and the semiconductor package device 10 so as to prevent the to-be-tested points 20 of the semiconductor package device 10 from being damaged.

However, the conventional test socket has the following drawbacks.

1. The structure of the probe 16 is complicated and may cost high when the probe is made very fine.

2. Since the probes 16 are fixedly mounted in the base 14, the overall socket has to be treated as wasted material when one of the probes 16 is damaged.

3. When the types or serial numbers of the semiconductor package devices 10 are not the same to cause different positions of the to-be-tested points 20, the socket cannot be suitable for the devices. Thus, after a batch of devices is tested, the socket cannot be used and has to be stored or treated as wasted material. In addition, the probes 16 cannot be recycled, and the problems of wasting sources and damaging the environment are thus caused.

In view of the above-mentioned problems, the invention provides a socket for testing a semiconductor package device without causing the above-mentioned drawbacks.

### SUMMARY OF THE INVENTION

It is therefore an object of the invention to provide a socket for testing a semiconductor package device, which is easy to be manufactured and can lower the testing cost.

Another object of the invention is to provide a socket for testing a semiconductor package device, wherein the socket can be reused and recycled so that the sources can be saved.

Still another object of the invention is to provide a socket for testing a semiconductor package device, wherein the socket is easy to be maintained and replaced, so that the cost of the test socket can be saved.

Yet still another object of the invention is to provide a socket for testing a semiconductor package device, wherein the cost of the probes are relatively low and thus the cost of the socket is also low.

To achieve the above-mentioned objects, the invention provides a socket including a pin board unit, a plurality of resilient members, a plurality of probe bodies and a plurality of electroconductive elements. The pin board unit is formed with a plurality of pin holes corresponding to the to-be-tested points and has one end formed with a cavity with a suitable size. The cavity is used to precisely position the semiconductor package device. The resilient members are arranged within the pin holes, respectively. Each probe body includes a first section and a second section. The first sections are inserted into the pin holes and in contact with the resilient members, respectively. The second sections are exposed from the pin holes and located within the cavity in order to contact the to-be-tested points, respectively. Each electroconductive element includes an upper section and a lower section. The upper sections are inserted into the pin holes and in contact with the resilient members, and the lower sections are exposed from the pin holes, respectively.

Accordingly, the second sections may contact the to-be-tested points for transferring test signals from the electroconductive elements to the printed circuit board, and then to the test machine.

### BRIEF DESCRIPTION OF THE DRAWINGS

FIG. 1 is a cross-sectional view showing a conventional test socket.

FIG. 2 is an enlarged view showing a probe of FIG. 1.

FIG. 3 is an exploded view showing the socket of the invention.

FIG. 4 is a cross-sectional view showing the combination of the socket of the invention.

FIG. 5 is a drawing showing the implementation of the invention.

FIG. 6 is a drawing showing another implementation of the invention.

FIG. 7 is an enlarged view showing the electroconductive element.

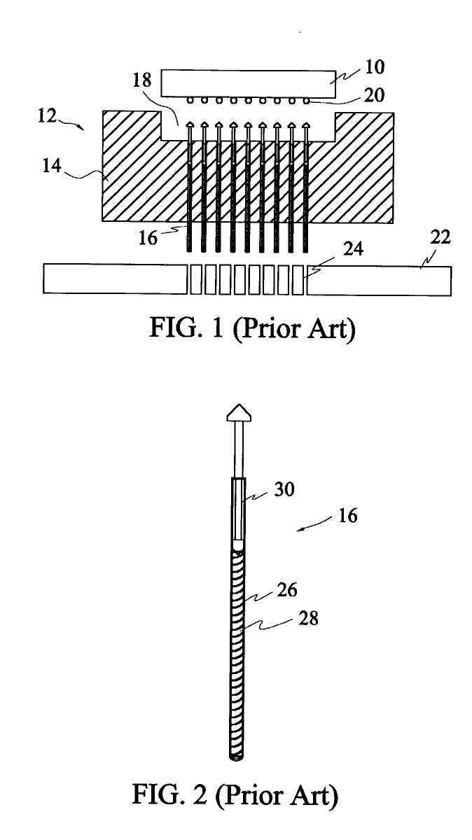

### DETAILED DESCRIPTION OF THE INVENTION

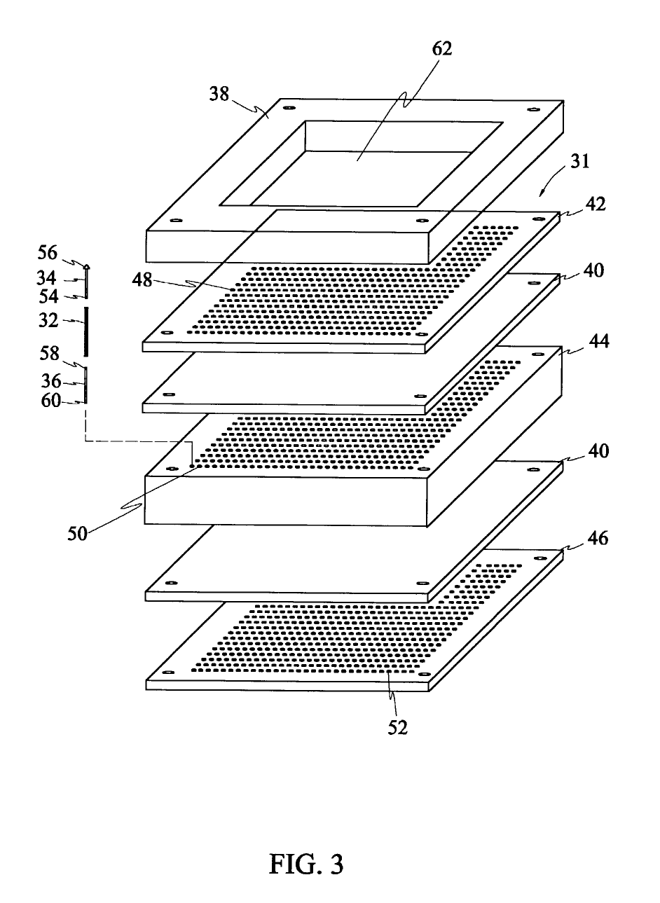

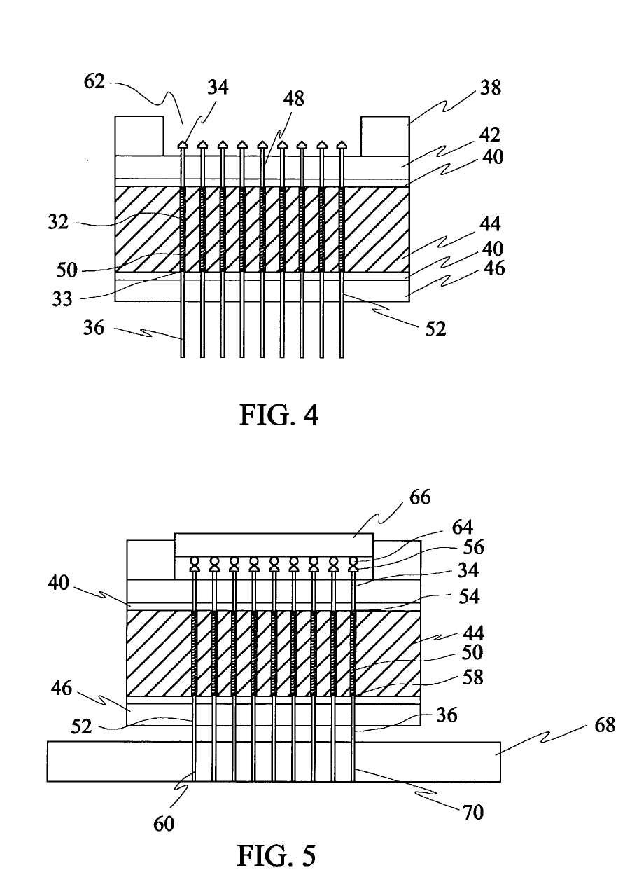

Referring to FIGS. 3 and 4, the socket in accordance with one embodiment of the invention for testing a semiconductor package device includes a pin board unit 31, a plurality of resilient members 32, a plurality of probe bodies 34, a plurality of electroconductive elements 36 and fixing members 40.

In this embodiment, the pin board unit 31 includes an upper pin board 42, a middle pin board 44 and a lower pin board 46. The upper pin board 42 is formed with upper pin holes 48 arranged in a grid-like and crisscross fashion, the middle pin board 44 is formed with middle pin holes 50 arranged in a grid-like and crisscross fashion, and the lower pin board 46 is formed with lower pin holes 52 arranged in a grid-like and crisscross fashion. Each middle pin hole 50 has a diameter greater than the diameters of each upper pin hole 48 and each lower pin hole 52. In another embodiment, it is not necessary for the pin board unit 31 to formed with pin holes arranged in a grid-like and crisscross fashion, and only through holes have to be formed at positions corresponding to the to-be-tested points of the semiconductor package device.

A frame 38 is formed on the upper surface of the upper pin board 42. The frame 38 is formed with a cavity 62 having the size corresponding to that of the semiconductor package device. It should be noted that the frame 38 might be one portion of the upper pin board 42. Accordingly, the semiconductor package device can be precisely positioned within the cavity 62. Therefore, the to-be-tested points of the semiconductor package device can be precisely aligned with the upper pin holes 48 of the upper pin board 42, respectively.

The resilient members 32 are arranged within the middle pin holes 50 of the middle pin board 44, respectively. By the clamping action between the upper pin board 42 and the lower pin board 46, it is possible to mount the resilient members 32 within the middle pin holes 50 of the middle pin board 44, respectively. Each of the resilient members 32 can be elastically restored and has one end formed with a support portion 33 having gradually reduced inner diameters.

Each probe body 34 includes a first section 54 and a second section 56. The first sections 54 are inserted into the upper pin holes 48 and the middle pin holes 50 so as to contact the support portions 33 of the resilient members 32, respectively. The second sections 56 are exposed from the upper pin holes 48 and are located within the cavity 62.

Each electroconductive element 36 includes an upper section 58 and a lower section 60. The upper sections 58 are inserted into the lower pin holes 52 and the middle pin holes 50 from the lower pin board 46 so as to contact the resilient members 32, respectively. The lower sections 60 are exposed from the lower pin holes 52 for transferring test signals to a test machine (not shown).

The fixing members 40 may be flexible boards and are arranged between the upper pin board 42 and the middle pin board 44, and between the middle pin board 44 and the lower pin board 46, respectively. The flexible boards are penetrated by the probe bodies 34 and the electroconductive elements 36 to hold the probe bodies 34 and the electroconductive elements 36. The probe bodies 34 and the electroconductive elements 36 are retractable and can be moved up and down by way of the elasticity of the flexible boards.

As shown in FIG. 4, the pin holes of the pin board unit 31 are formed at positions corresponding to the positions of the to-be-tested points of the semiconductor package device. The resilient members 32, probe bodies 34 and electroconductive elements 36 are arranged within the middle pin holes 50, respectively. The probe bodies 34 and electroconductive elements 36 penetrate through the fixing members 40, contact the resilient members 32, and are held by the fixing members 40.

Please refer to FIG. 5. The socket of the invention is used for testing a semiconductor package device 66 having a plurality of to-be-tested points 64. The resilient members 32 are arranged within the middle pin holes 50 at positions corresponding to the to-be-tested points 64 of the semiconductor package device 66. The first sections 54 of the probe bodies 34 are inserted into the middle pin holes 50 provided with the resilient members 32, and in contact with the resilient members 32, respectively. The second sections 56 are exposed from the upper pin holes 48 of the upper pin board 42 and in contact with the to-be-tested points 64 of the semiconductor package device 66. The second sections 56 also penetrate the fixing member 40 so that the fixing member may effectively position the probe bodies 34.

The upper sections 58 of the electroconductive elements 36 are inserted into the lower pin holes 52 and the middle pin holes 50 from the lower pin board 46 and in contact with the resilient members 32, respectively. The lower sections 60 are exposed from the lower pin holes 52 for electrically connecting to and mounting to the predetermined through holes 70 formed in the printed circuit board 68. Accordingly, the test signals may be transferred to the printed circuit board 68, and then to the test machine (not shown).

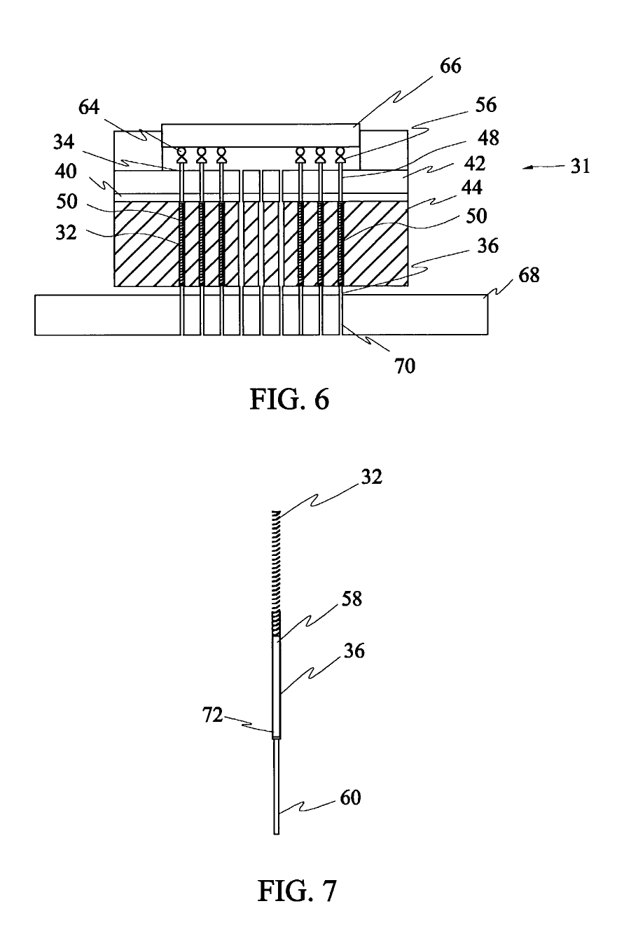

Referring to FIG. 6, the socket in accordance with another embodiment of the invention has a middle pin board unit 31 only including an upper pin board 42 and a middle pin board 44. The upper pin board 42 is formed with upper pin holes 48 arranged in a grid-like and crisscross fashion, while the middle pin board 44 is formed with middle pin holes 50 arranged in a grid-like and crisscross fashion. The resilient members 32 are arranged within the middle pin holes 50 at positions corresponding to the to-be-tested points 64 of the semiconductor package device 66, respectively. The fixing member 40 is arranged between the upper pin board 42 and the middle pin board 44. The first sections 54 of the probe bodies 34 are inserted into the middle pin holes 50 provided with the resilient members 32 and in contact with the resilient members 32, respectively. The second sections 56 of the probe bodies 34 are exposed from the upper pin holes 48, respectively, and are located within the cavity 62 formed on the upper pin board 42. The second sections 56 contact the to-be-tested points 64 of the semiconductor package device 66 and penetrate through the fixing member 40, which may effectively position the probe bodies 34.

Referring to FIGS. 6 and 7, the upper section 58 of the electroconductive element 36 is inserted into the middle pin hole 50 of the middle pin board 44 and is mounted in the middle pin board 44. The electroconductive element 36 is formed with a chamber 72 for receiving the resilient member 32. The lower section 60 of the electroconductive element 36 is exposed from the middle pin hole 50 and is mounted within the predetermined through holes 70 of the printed circuit board 68. Accordingly, the test signals can be transferred to the printed circuit board 68, and then to the test machine (not shown).

According to the above-mentioned structure, the socket of the invention has the following advantages.

1. Since the resilient member 32 and probe body 34 are separated and not contained in a sleeve, the manufacturing cost is relatively low when they are made very thin and small.

2. When one probe body 34 in the socket is damaged, the probe body 34 can be directly replaced and the overall socket can still be used.

3. After a batch of semiconductor package devices is tested, the positions of the probe bodies 34 can be adjusted, and the socket can be used again.

4. Since the cavity 62 formed on the upper pin board 42 may have a size precisely matching that of the semiconductor package device 66, the to-be-tested points 64 may precisely contact the probe bodies 34 when the semiconductor package device 66 is placed within the cavity 62.

While the invention has been described by way of examples and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

1. A socket for testing a semiconductor package device having a plurality of to-be-tested points and for transferring test signals to a test machine, the socket comprising:
a pin board unit formed with a plurality of pin holes at positions corresponding to the to-be-tested points of the semiconductor package device, the pin board unit having one end formed with a cavity having a size matching that of the semiconductor package device for positioning the semiconductor package device within the cavity;
a plurality of resilient members arranged within the pin holes of the pin board unit, respectively;
a plurality of probe bodies, each of which having a first section and a second section, the first sections being inserted into the pin holes and in contact with the resilient members, respectively, and the second sections being exposed from the pin holes and in contact with the to-be-tested points; and
a plurality of electroconductive elements, each of which having an upper section and a lower section, the upper sections contacting the resilient members within the pin holes, respectively, and the lower sections being exposed from the pin holes for transferring the test signals to the test machine.

2. The socket according to claim 1, wherein the pin board unit comprises an upper pin board formed with upper pin holes, a middle pin board formed with middle pin holes, and a lower pin board formed with lower pin holes, the resilient members are located within the middle pin holes, and the cavity is formed on the upper pin board.

3. The socket according to claim 2, wherein the pin board unit further comprises two fixing members arranged between the upper and middle pin boards and between the middle and lower pin boards, respectively, for holding the probe bodies and the electroconductive elements.

4. The socket according to claim 3, wherein the fixing members are flexible boards through which the probe bodies and the electroconductive elements penetrate, for clamping and holding the probe bodies and the electroconductive elements.

5. The socket according to claim 1, wherein the pin board unit comprises an upper pin board formed with upper pin holes, and a middle pin board formed with middle pin holes, the upper sections of the electroconductive elements are inserted into the middle pin holes and in contact with the resilient members, respectively, and the cavity is formed on the upper pin board.

6. The socket according to claim 1, wherein the upper sections of the electroconductive elements are formed with chambers for receiving and contacting the resilient members, respectively.

7. The socket according to claim 5, wherein the pin board unit further comprises a fixing member between the upper and middle pin boards, for holding the probe bodies.

8. The socket according to claim 7, wherein the fixing member is a flexible board through which the probe bodies penetrate, for clamping and holding the probe bodies.

9. The socket according to claim 1, wherein the lower sections of the electroconductive elements are inserted into predetermined through holes formed on a printed circuit board, for transferring the test signals from the printed circuit board to the test machine.

10. A socket for testing a semiconductor package device having a plurality of to-be-tested points and for transferring test signals to a test machine, the socket comprising:
a pin board unit formed with pin holes arranged in a grid-like and crisscross fashion and having one end formed with a cavity having a size matching that of the semiconductor package device for positioning the semiconductor package device within the cavity;
a plurality of resilient members inserted into the pin holes corresponding to the to-be-tested points of the semiconductor package device, respectively;
a plurality of probe bodies, each of which having a first section and a second section, the first sections being inserted into the pin holes provided with the resilient members and in contact with the resilient members, and the second sections being exposed from the pin holes and in contact with the to-be-tested points, respectively;
a plurality of electroconductive elements, each of which having an upper section and a lower section, the upper sections being in contact with the resilient members within the pin holes, and the lower sections being exposed from the pin holes for transferring the test signals to the test machine, respectively.

11. The socket according to claim 10, wherein the pin board unit comprises an upper pin board formed with upper pin holes, a middle pin board formed with middle pin holes, and a lower pin board formed with lower pin holes, all of the pin holes are arranged in a grid-like and crisscross fashion, and the resilient members are located within the middle pin holes, respectively.

12. The socket according to claim 11, wherein the pin board unit further comprises two fixing members arranged between the upper and middle pin boards and between the middle and lower pin boards, respectively, for holding the probe bodies and the electroconductive elements.

13. The socket according to claim 12, wherein the fixing members are flexible boards through which the probe bodies and the electroconductive elements penetrate, for clamping and holding the probe bodies and the electroconductive elements.

14. The socket according to claim 10, wherein the pin board unit comprises an upper pin board formed with upper pin holes, and a middle pin board formed with middle pin holes, all the pin holes are arranged in a grid-like and crisscross fashion, and the upper sections of the electroconductive elements are inserted into the middle pin holes and in contact with the resilient members, respectively.

15. The socket according to claim 10, wherein the upper sections of the electroconductive elements are formed with chambers for receiving and contacting the resilient members, respectively.

16. The socket according to claim 14, wherein the pin board unit further comprises a fixing member between the upper and middle pin boards, for holding the probe bodies.

17. The socket according to claim 16, wherein the fixing member is a flexible board through which the probe bodies penetrate, for clamping and holding the probe bodies.

18. The socket according to claim 10, wherein the lower sections of the electroconductive elements are inserted into predetermined through holes formed on a printed circuit board, for transferring the test signals from the printed circuit board to the test machine.

19. A socket for testing a semiconductor package device having a plurality of to-be-tested points and for transferring test signals to a test machine, the socket comprising:
a pin board unit formed with a plurality of pin holes at positions corresponding to the to-be-tested points of the semiconductor package device, the pin board unit having one end formed with a cavity having a size matching that of the semiconductor package device for positioning the semiconductor package device within the cavity;
a plurality of resilient members arranged within the pin holes of the pin board unit, respectively, and each having one end formed with a support portion with gradually reduced inner diameters;
a plurality of probe bodies, each of which having a first section and a second section, the first sections being inserted into the pin holes and in contact with the support portions of the resilient members, and the second sections being exposed from the pin holes and in contact with the to-be-tested points, respectively; and
a plurality of electroconductive elements, each of which having an upper section and a lower section, the upper sections contacting the resilient members within the pin holes, respectively, and the lower sections being exposed from the pin holes for transferring the test signals to the test machine.

20. The socket according to claim 19, wherein the pin board unit comprises an upper pin board formed with upper pin holes, a middle pin board formed with middle pin holes, and a lower pin board formed with lower pin holes, the resilient members are located within the middle pin holes, and the cavity is formed on the upper pin board.

21. The socket according to claim 20, wherein the pin board unit further comprises two fixing members arranged between the upper and middle pin boards and between the middle and lower pin boards, respectively, for holding the probe bodies and the electroconductive elements.

22. The socket according to claim 21, wherein the fixing members are flexible boards through which the probe bodies and the electroconductive elements penetrate, for clamping and holding the probe bodies and the electroconductive elements.

23. The socket according to claim 19, wherein the pin board unit comprises an upper pin board formed with upper pin holes, and a middle pin board formed with middle pin holes, the upper sections of the electroconductive elements are inserted into the middle pin holes and in contact with the resilient members, respectively, and the cavity is formed on the upper pin board.

24. The socket according to claim 19, wherein the upper sections of the electroconductive elements are formed with chambers for receiving the resilient members and contacting the resilient members, respectively.

25. The socket according to claim 23, wherein the pin board unit further comprises a fixing member between the upper and middle pin boards, for holding the probe bodies.

26. The socket according to claim 25, wherein the fixing member is a flexible board through which the probe bodies penetrate, for clamping and holding the probe bodies.

27. The socket according to claim 19, wherein the lower sections of the electroconductive elements are inserted into predetermined through holes formed on a printed circuit board, for transferring the test signals from the printed circuit board to the test machine.
